(19) United States
(12) Patent Application Publication
(10) Pub. No.: US 2024/0071841 A1
(43) Pub. Date: Feb. 29, 2024

(54) LAYOUT METHOD OF SEMICONDUCTOR, INSPECTION METHOD OF WAFER, MANUFACTURING METHOD OF THE WAFER AND MANUFACTURING METHOD OF MULTI-CHIP PACKAGE

(71) Applicant: Samsung Electronics Co., Ltd., Suwon-si (KR)

(72) Inventors: Sumin PARK, Suwon-si (KR); Taeseong KIM, Suwon-si (KR); Jaehyung PARK, Suwon-si (KR); Kyuha LEE, Suwon-si (KR); Yeojin LEE, Suwon-si (KR); Kwangjin MOON, Suwon-si (KR); Hojin LEE, Suwon-si (KR)

(73) Assignee: Samsung Electronics Co., Ltd., Suwon-si (KR)

(21) Appl. No.: 18/302,401

(22) Filed: Apr. 18, 2023

(30) Foreign Application Priority Data
Aug. 30, 2022 (KR) 10-2022-0109015

(51) Int. Cl. H01L 21/66; B24B 37/013; G06F 30/392; H01L 23/00

(52) U.S. Cl. CPC H01L 22/20; B24B 37/013; G06F 30/392; H01L 22/32; H01L 24/03; H01L 24/05; H01L 2224/03845; H01L 2224/05571; H01L 2224/05647

(57) ABSTRACT

In a manufacturing method of a wafer, the method including: an operation of preparing a wafer including a semiconductor chip region and a test region, measuring a measurement region included in the test region with an atomic force microscope (AFM), the measurement region including a plurality of metal lines having a constant line width and a constant pitch; determining a surface roughness value of the test region based on a result of the measuring of the measurement region; determining a step difference value of the metal lines of the test region based on the surface roughness value; and determining a step difference value of bonding pads in the semiconductor chip region based on the step difference value of the metal lines.

### CROSS-REFERENCE TO RELATED APPLICATION

This application claims the priority and benefit of Korean Patent Application No. 10-2022-0109015, filed on Aug. 30, 2022, with the Korean Intellectual Property Office, the inventive concepts of which is incorporated herein by reference.

### BACKGROUND

### 1. Field

The present inventive concepts relate to a layout method of a semiconductor, an inspection method of a wafer, a manufacturing method of the wafer, and a manufacturing method of a multichip package.

### 2. Description of Related Art

In a wafer-to-wafer bonding process for manufacturing a multichip package in which at least two semiconductor chips are stacked, pad-to-pad direct bonding may be performed without using solder bumps.

Wafers for bonding may include bonding pads and an insulating layer having the bonding pads on an upper surface thereof. When the bonding pads protrude further than a predetermined, set, and/or otherwise determined height as compared to the insulating layer, it may be difficult for the insulating layers to properly bond during the bonding of the wafers, and when the bonding pads are recessed beyond the predetermined, set, and/or otherwise determined depth compared to the insulating layer electrical characteristics between the bonding pads may be deteriorated.

### SUMMARY

An aspect of the present inventive concepts is to provide an inspection method of a wafer capable of automatically monitoring whether bonding pads and an insulating layer on an upper surface of the wafer have a step difference within a predetermined range.

An aspect of the present inventive concepts is to provide a layout method of a test pattern for monitoring a step difference between bonding pads on an upper surface of a wafer and an insulating layer.

An aspect of the present inventive concepts is to provide a manufacturing method of a wafer in which bonding pads and a test pattern are formed on an upper surface of a wafer, and a step difference between the bonding pads and an insulating layer is within a predetermined range based on a monitoring result using the test pattern.

An aspect of the present inventive concepts is to provide a method of manufacturing a multichip package through direct pad-to-pad bonding of wafers having bonding pads and a test pattern on an upper surface thereof.

According to an aspect of the present inventive concept, a manufacturing method of a wafer is provided, the method including: preparing the wafer, including a semiconductor chip region and a test region, such that an integrated circuit is formed in the semiconductor chip region; forming an insulating layer on an upper surface of the prepared wafer; forming a bonding pad pattern in the semiconductor chip region of the insulating layer; forming a line pattern having a constant line width and a constant pitch in the test region of the insulating layer; depositing a metal layer on the insulating layer; polishing the metal layer using a chemical mechanical polishing (CMP) process such that bonding pads and metal lines are formed based on the bonding pad pattern and the line pattern, respectively; determining a surface roughness value of the test region by measuring the test region in which the metal lines are formed using an atomic force microscope (AFM); determining a step difference value of the bonding pads of the semiconductor chip region with respect to the insulating layer, based on the surface roughness value of the test region; and selectively performing the CMP process when the step difference value of the bonding pads is not within a target step difference tolerance range.

According to an aspect of the present inventive concept, an inspection method of a wafer including a semiconductor chip region and a test region is provided, the method including: measuring a measurement region included in the test region with an atomic force microscope (AFM), the measurement region including a plurality of metal lines having a constant line width and a constant pitch; determining a surface roughness value of the test region based on a result of the measuring of the measurement region; determining a step difference value of the metal lines of the test region based on the surface roughness value; and determining a step difference value of bonding pads in the semiconductor chip region based on the step difference value of the metal lines.

According to an aspect of the present inventive concept, a layout method of a semiconductor is provided, the method including: determining a size of a test region based on a stage error of an atomic force microscope (AFM) and a size of a measurement region of the AFM; setting a measurable step difference range based on a signal noise level of the AFM;

designing a bonding pad pattern in a semiconductor chip region of the semiconductor wafer; designing a line pattern having a constant line width and a constant pitch in the test region of the semiconductor wafer; deriving a correlation between a step difference of bonding pads and a step difference of metal lines, the bonding pads and the metal lines generated based on the bonding pad pattern and the line pattern, respectively; verifying, based on the correlation, whether the step difference of the metal lines is included in the measurable step difference range when the step difference of the bonding pads is included in a target step difference range; and selectively adjusting at least one of the line width or the pitch of the line pattern based on a result of the verifying whether the step difference of the metal lines is included in the measurable step difference range.

According to an aspect of the present inventive concept, a manufacturing method of a multichip is provided, the method including: forming a first wafer including a first integrated circuit, first bonding pads on a first bonding surface, and first metal lines the first bonding pads electrically connected to the first integrated circuit, and the first metal lines electrically isolated from the integrated circuit forming a second wafer including a second integrated circuit, second bonding pads on a second bonding surface, and second metal lines, the second bonding pads electrically connected to the second integrated circuit and the second metal lines electrically isolated from the integrated circuit; and bonding the first bonding surface and the second bonding surface so that the first bonding pads and the second bonding pads are aligned.

### BRIEF DESCRIPTION OF DRAWINGS

The above and other aspects, features, and advantages of the present inventive concepts will be more clearly understood from the following detailed description taken in conjunction with the accompanying drawings, in which:

FIG. 1 is a view for illustrating a pad-to-pad direct bonding method for manufacturing a multichip package;

FIG. 2 is a view for illustrating a manufacturing method of a bonding layer including an insulating layer and bonding pads on an upper surface of a wafer;

FIG. 3 is a diagram for illustrating poor bonding between bonding layers that may be caused by a step difference between bonding pads and an insulating layer;

FIG. 4 is a diagram illustrating a water according to at least one example embodiment of the present inventive concepts;

FIGS. 5A to 5D are diagrams for illustrating in detail a semiconductor chip region and a test region of a wafer according to some example embodiments of the present inventive concepts;

FIGS. 6A to 6B are diagrams for illustrating a comparison between a test pattern according to a comparative example and a test pattern according to an example embodiment of the present inventive concepts;

FIG. 7 is a view for illustrating in detail a test pattern region according to at least one example embodiment of the present inventive concepts;

FIGS. 8A to 8E are diagrams for illustrating a width and a pitch of a test pattern according to some example embodiments of the present inventive concepts;

FIG. 9 is a flowchart illustrating a test pattern layout method according to at least one example embodiment of the present inventive concepts;

FIG. 10 is a flowchart illustrating a wafer inspection method according to at least one example embodiment of the present inventive concepts;

FIG. 11 is a flowchart illustrating a manufacturing method of a wafer according to at least one example embodiment of the present inventive concepts;

FIG. 12 is a flowchart illustrating a manufacturing method of a multichip package according to at least one example embodiment of the present inventive concepts; and

FIG. 13 is a diagram illustrating a wafer monitoring apparatus according to at east one example embodiment of the present inventive concepts.

### DETAILED DESCRIPTION

Hereinafter, preferred example embodiments of the present inventive concepts will be described with reference to the accompanying drawings as follows, wherein like reference numerals refer to like elements throughout. In this regard, the present embodiments may have different forms and should not be construed as being limited to the descriptions set forth herein.

When the terms “about” or “substantially” are used in this specification in connection with a numerical value, it is intended that the associated numerical value includes a manufacturing tolerance (e.g., ±10%) around the stated numerical value. Further, regardless of whether numerical values are modified as “about” or “substantially,” it will be understood that these values should be construed as including a manufacturing or operational tolerance (e.g., ±10%) around the stated numerical values.

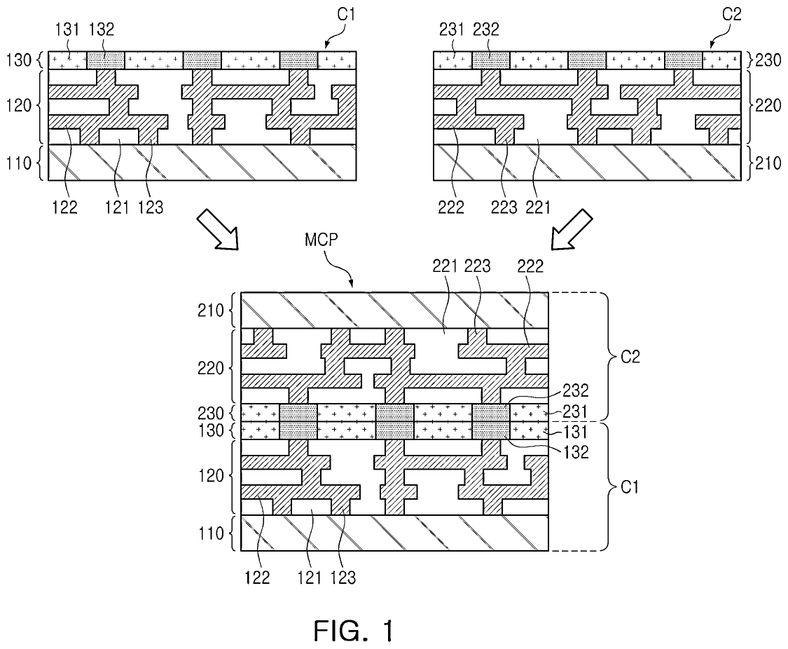

FIG. 1 is a view for illustrating a pad-to-pad direct bonding method for manufacturing a multichip package.

Referring to FIG. 1, a multichip package MCP may include a first semiconductor chip C1 and a second semiconductor chip C2. The first semiconductor chip C1 and the second semiconductor chip C2 may have bonding pads 132 and 232 on an upper surface thereof. The multichip package MCP may be formed by directly bonding the bonding pads 132 and 232, e.g., by applying heat and pressure while upper surfaces of the first semiconductor chip C1 and the second semiconductor chip C2 are in contact with each other. For example, when the bonding pads 132 and 232 are formed of copper (Cu), a bonding method of directly bonding the bonding pads 132 and 232 may be referred to as a copper-to-copper (Cu-to-Cu) hybrid bonding method.

According to some embodiments, the first semiconductor chip C1 may include a substrate 110, an interconnection layer 120, and a bonding layer 130. The substrate 110 may include a plurality of logic devices such as transistors, capacitors, photodiodes, and/or the like. The interconnection layer 120 may include metal interconnections for electrically connecting a plurality of logic devices. More specifically, the interconnection layer 120 may include an insulating layer 121, interconnections 122 extending in a direction parallel to an upper surface of the substrate 110, and vias 123 electrically connecting the interconnections 122 in a direction perpendicular to the upper surface of the substrate 110. A plurality of logic devices included in the substrate 110 and metal interconnections included in the interconnection layer 120 may constitute an integrated circuit.

The bonding layer 130 may include an insulating layer 131 and bonding pads 132 surrounded by the insulating layer 131. The bonding pads 132 may include a lower surface facing the substrate 110 and an upper surface opposite to the lower surface. Lower surfaces of the bonding pads 132 may be electrically connected to the via 123, and upper surfaces of the bonding pads 132 may be exposed externally. The insulating layer 131 may be formed of a material, different from that of the insulating layer 121. For example, the insulating layer 121 may be formed of silicon oxide such as SiO₂, and the insulating layer 131 may be formed of silicon carbon nitride (SiCN). The bonding pads 132 may be formed of copper (Cu) as described above.

The second semiconductor chip C2 may include a substrate 210, an interconnection layer 220, and a bonding layer 230. The substrate 210 may include a plurality of logic devices, like the substrate 110, and the interconnection layer 220 may include metal interconnections for electrically connecting the plurality of logic devices, like the interconnection layer 120. A plurality of logic devices included in the substrate 210 and metal interconnections included in the interconnection layer 220 may constitute an integrated circuit.

The bonding layer 230 may include an insulating layer 231 and bonding pads 232. The bonding layer 230 may comprise the same (or similar materials) as the bonding layer 120. For example, the insulating layer 231 may be formed of silicon carbon nitride (SiCN), and the bonding pads may be formed of copper (Cu). The bonding pads 132 and the bonding pad 232 may be symmetrically disposed on upper surfaces of the bonding layer 130 and the bonding layer 230. More specifically, when the bonding pads 132 and 232 are bonded by applying heat and pressure while upper surfaces of the first semiconductor chip C1 and the second semiconductor chip C2 are in contact with each other, an integrated circuit of the first semiconductor chip C1 and an integrated circuit of the second semiconductor chip C2 may be electrically connected.

The first semiconductor chip C1 and the second semiconductor chip C2 may be bonded before being separated from the wafer. For example, a first semiconductor chip C1 may be formed on a first wafer, and a second semiconductor chip C2 may be formed on a second wafer. The bonding pads 132 and 232 may be bonded to each other by turning over the second wafer and applying heat and pressure while an upper surface of the first wafer and an upper surface of the bonding wafer are in contact with each other. The first wafer may be referred to as a base wafer, a lower wafer, or the like, and the second wafer may be referred to as a bonded wafer, an upper wafer, or the like.

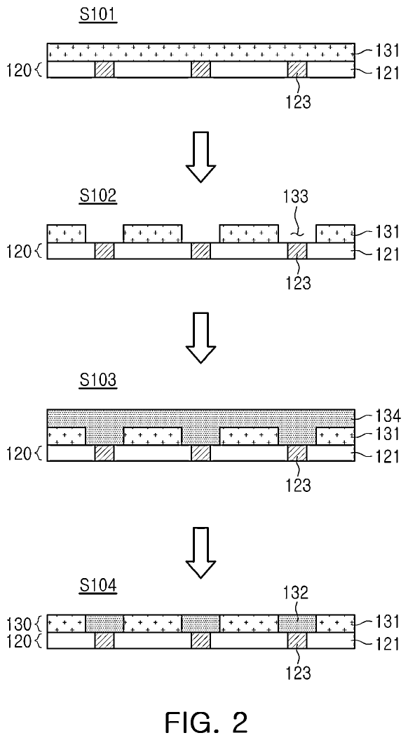

FIG. 2 is a view for illustrating a manufacturing method of an insulating layer and a bonding layer including bonding pads on an upper surface of a wafer. More specifically, FIG. 2 illustrates a manufacturing method of a portion of the interconnection layer 120 and the bonding layer 130 included in the first semiconductor chip C1 described with reference to FIG. 1. It will be understood that the same and/or a similar method may be applied, e.g., with regards to the second semiconductor chip C2.

Referring to FIG. 2, an insulating layer 131 may be deposited on an upper surface of the interconnection layer 120 in operation S101. In operation S102, a trench 133 may be formed at a predetermined (and/or otherwise determined) position of the insulating layer 131. For example, a photoresist may be applied to a position corresponding to a via 123 of the interconnection layer 120, and a trench 133 may be formed through a photo process, though the example embodiments are not limited thereto. The via 123 may be exposed externally through the trench 133.

In operation S103, a metal layer 134 covering the insulating layer 131 may be deposited. In operation S104, a chemical mechanical polishing (CMP) process for removing a metal layer 134 deposited on an upper surface of the insulating layer 131 may be performed. A metal material remaining in the trench 133 may be the bonding pad 132.

Meanwhile, as illustrated in FIG. 2, it is preferable that an upper surface of the insulating layer 131 and an upper surface of the bonding pad 132 form a coplanar surface, but due to an error in the CMP process, a step difference may occur on the upper surface of the insulating layer 131 and/or an upper surface of the bonding pad 132. The step difference of the bonding pad 132 with respect to the insulating layer 131 may cause a bonding defect when the bonding layer 130 is bonded to the bonding layer 230.

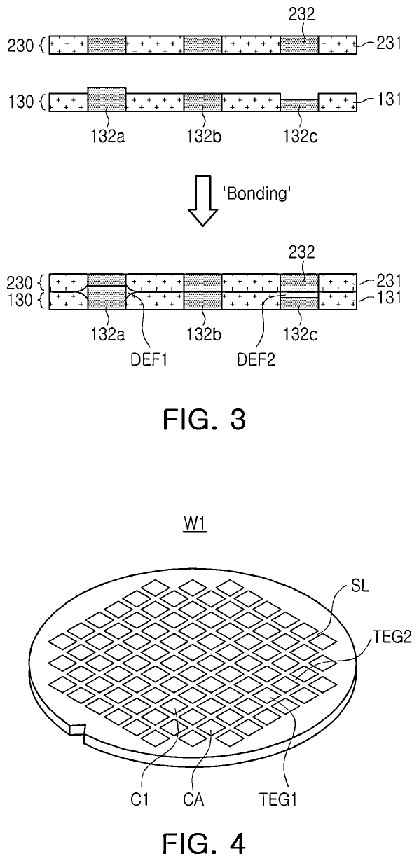

FIG. 3 is a view for illustrating poor bonding between bonding layers that may be caused by a step difference between bonding pads and an insulating layer.

FIG. 3 illustrates a bonding layer 130 of the first semiconductor chip C1 and a bonding layer 230 of the second semiconductor chip C2. FIG. 3 illustrates bonding pads 132a, 132b, and 132c surrounded by an insulating layer 131. The bonding pad 132a may protrude from the insulating layer 131 and have a positive step difference with respect to the insulating layer 131, the bonding pad 132b may have no step difference with respect to the insulating layer 131, and the bonding pad 132c may be recessed from the insulating layer 131 to have a negative step difference with respect to the insulating layer 131. Meanwhile, for simplicity of description, the bonding pads 232 are illustrated as having no step difference with respect to the insulating layer 231.

When the bonding layer 130 and the bonding layer 230 are bonded to each other, the bonding pads 132a and 132c may cause bonding defects DEF1 and DEF2. For example, when the bonding pad 132a protrudes, the bonding pads 132a and 232 may be successfully bonded, but a bonding defect DEF1 called a bonding void may occur in adjacent insulating layers 131 and 231. On the other hand, when the bonding pad 132c is recessed, the adjacent insulating layers 131 and 231 may be successfully bonded, but a bonding defect DEF2 in which the bonding pads 132c and 232 are not sufficiently contacted, so that electrical characteristics are deteriorated may occur. Meanwhile, the bonding pad 132b having no step difference with respect to the insulating layer 131 may be normally bonded to the bonding pad 232, and adjacent insulating layers 131 and 231 may also be normally bonded to each other.

In short, in order for semiconductor chips having a bonding layer to be successfully bonded, it is preferable that the bonding pad be formed to have a step difference within a tolerance range with respect to the insulating layer through a CMP process. For example, a target step difference may be set so that the bonding pad has a step difference within (0±10 Å) with respect to the insulating layer. In order to check whether the bonding pad has a step difference within a target step difference, the step difference of the bonding pad must be monitored.

A height of a surface of the semiconductor chip may be measured by an atomic force microscope (AFM). An AFM can generate a 2D image containing height information. For example, in a 2D image, a relatively high region is displayed in a light color, and a relatively low region is displayed in a dark color. The AFM can detect a bonding pad by, for example, searching for a bright color region, and monitor a step difference of the detected bonding pad.

However, when the bonding pad and the insulating layer have a step difference within (0±10 Å), the bonding pad may be displayed as a bright region or a dark region in the AFM image, and the color of the bonding pad and the insulating layer may be barely distinguished. Therefore, it may be difficult for the AFM to automatically detect the bonding pad from the insulating layer, and as a result, it may be difficult to monitor the step difference of the bonding pad.

According to at least one example embodiment of the present inventive concepts, a test element group (TEG) including metal lines as well as a semiconductor chip including bonding pads may be further formed on a wafer. The metal lines may be formed of the same metal material as the bonding pads, and may be formed by the same CMP process. The metal lines may be formed to have a step difference of sufficient size to be detected by the AFM even in the same CMP process as the bonding pads.

Since the metal lines and the bonding pads are generated by the same CMP process, there may be a high correlation between the step difference of the metal lines and the step difference of the bonding pads. Accordingly, the step difference of the bonding pads may be calculated based on a result of measuring the metal lines by AFM. Accordingly, since monitoring of bonding pads formed on the wafer can be automated, mass production of a wafer including a bonding layer can be performed. Furthermore, yield of a multichip package produced using mass-produced wafers may be improved.

FIG. 4 is a diagram illustrating a wafer according to at least one example embodiment of the present inventive concepts.

Referring to FIG. 4, a wafer W1 may include a plurality of main chip regions CA and a scribe lane SL for partitioning the plurality of main chip regions CA.

A first semiconductor chip C1 may be formed in at least a portion of the plurality of main chip regions CA of the wafer W1. The first semiconductor chip C1 may include the bonding layer 130 as described with reference to FIGS. 1 to 3. A region in which the first semiconductor chip C1 is formed among the main chip regions CA may be referred to as a first semiconductor chip region C1.

A TEG may be further formed on the wafer W1. According to implementation, the TEG may be formed in a first test region TEG1 included in the plurality of main chip regions CA, and/or may be formed in a second test region TEG2 included in the scribe lane SL.

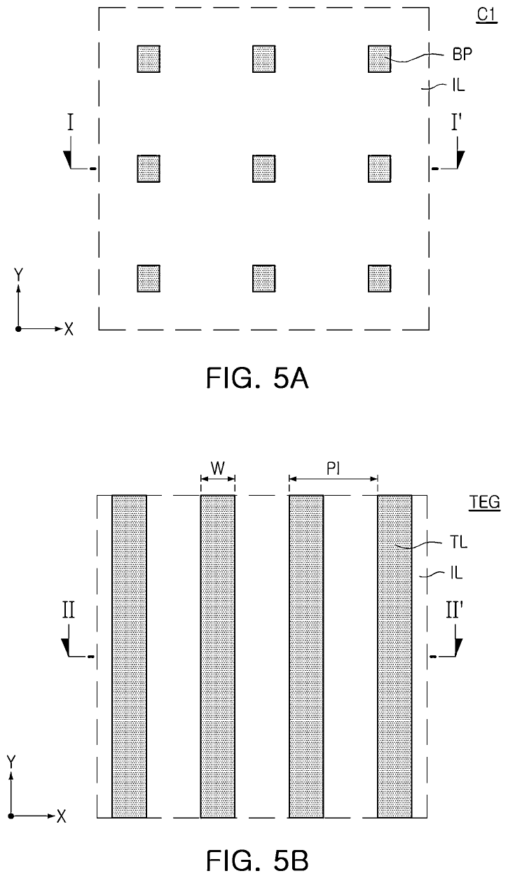

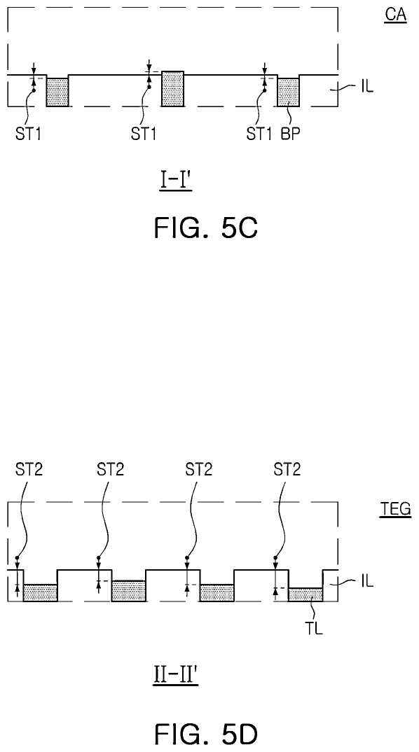

FIGS. 5A to 5D are diagrams for illustrating in detail a semiconductor chip region and a test region of a wafer according to some example embodiments of the present inventive concepts.

FIG. 5A illustrates a portion of an upper surface of the first semiconductor chip region C1 of the wafer W1 described with reference to FIG. 4, and FIG. 5B illustrates a portion of an upper surface of the test region TEG of the wafer W1. The test region TEG may correspond to the first test region TEG1 or the second test region TEG2, described with reference to FIG. 4. FIG. 5C is a cross-sectional view in the I-I′ direction of FIG. 5A, and FIG. 5D is a cross-sectional view in the II-II′ direction of FIG. 5B.

Referring to FIG. 5A, an upper surface of the first semiconductor chip region C1 may include bonding pads BP and an insulating layer IL surrounding the bonding pads BP. The bonding pads BP may have a circular and/or polygonal (e.g., a rectangular) shape.

Referring to FIG. 5B, an upper surface of the test region TEG may include metal lines TL and an insulating layer IL between the metal lines TL. The metal lines TL may comprise line shapes spaced apart from each other in a first direction X, parallel to the upper surface of the test region TEG, and extending in a second direction Y, parallel to the upper surface of the test region TEG and perpendicular to the first direction X. The metal line TL and the bonding pad BP may be formed of the same material, for example, copper (Cu), and the insulating layer IL may be formed of silicon carbon nitride (SiCN).

As described above, the bonding pads BP of the chip region CA and the metal lines TL of the test region TEG may be generated through the same CMP process. However, depending on the shape, size, and density of each of the bonding pads BP and the metal lines TL, a difference may occur between a step difference of the bonding pads BP and a step difference of the metal lines TL. Nevertheless, there may be a high correlation between the step difference of the bonding pads BP and the step difference of the metal lines TL.

Referring to FIG. 5C, a step difference ST1 of bonding pads BP of the chip region CA with respect to the insulating layer IL is illustrated. The bonding pads BP may have a positive step difference and/or a negative step difference. When a range of a target step difference of the bonding pads BP is out of a range of a measurable step difference of the AFM, it is difficult to check whether the bonding pads BP have a step difference within a target step difference. For example, the target step difference of the bonding pads BP may be within ±10 Å. As the quality and resolution of AFM is indirectly proportional to the speed of the AFM test, faster AFMs are more susceptible to signal noise, and slower AFMs increase production time and cost. For example, when the AFM is set such that the AFM has signal noise of about 2 nm (that is 20 Å), the AFM may normally detect most of the features of the semiconductor chip, but may only detect a bonding pad having a step difference of ±20 Å or more with respect to the insulating layer IL among the bonding pads BP. That is, as noted above, it may be difficult for the AFM to check whether the bonding pads BP satisfy the target step difference.

Referring to FIG. 5D, a step difference ST2 of the metal lines TL of the test region TEG with respect to the insulating layer IL is illustrated. According to some example embodiments of the present inventive concepts, by adjusting a line width and a pitch of the metal lines TL having a line shape, a layout of the test region TEG is formed so that the metal lines TL have a step difference within a measurable step difference range of the AFM. For example, the width and the pitch of the metal lines TL may be determined so that the metal lines TL have a negative step difference of 20 Å or more.

Meanwhile, the present inventive concepts do not exclude a case in which the line width and the pitch of the metal lines TL are designed to have a positive step difference of 20 Å or more. However, even if the layout is designed so that the metal lines TL have a positive step difference of 20 Å or more, there is a concern that the metal lines TL protruding by the CMP process may be worn to have a step difference of 20 Å or less. Therefore, it is preferable that the layout is designed so that the metal lines TL a negative step difference of 20 Å or more.

Meanwhile, according to at least some example embodiments of the present inventive concepts, instead of measuring a step difference of individual metal lines detected in an AFM image, a step difference value of the metal lines may be determined by calculating a surface roughness value of the overall AFM image. The surface roughness value may represent distribution of height values measured over an entire region of the AFM image; that is, a root mean square (RMS). The surface roughness value may have a high correlation with a step difference of the metal lines. For example, the greater the step difference between the metal lines, the greater the surface roughness value may appear. According to some example embodiments of the present inventive concepts, even if individual metal lines are not detected in the AFM image in which the test region TEG is measured, the step difference value of the metal lines may be determined by calculating the surface roughness value of the AFM image.

According to the description with reference to FIGS. 5A to 5D, the metal line TL may have a line shape, different from the rectangular shape of the bonding pad BP. When the test region TEG has a line-shaped metal line TL, an error in a surface roughness value obtained from an AFM image of the test region TEG may be reduced.

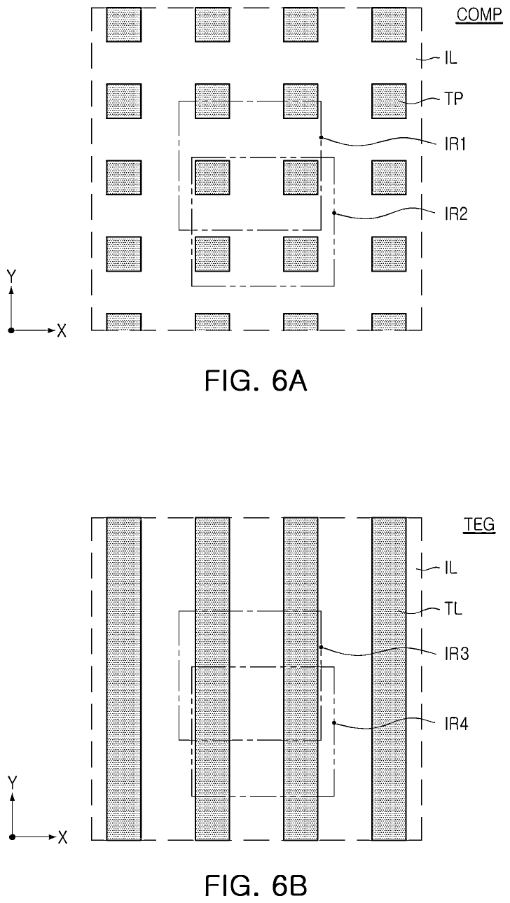

FIGS. 6A to 63 are diagrams for illustrating a comparison between a test pattern according to a comparative example and a test pattern according to an example embodiment of the present inventive concept. FIG. 6A illustrates a test region COMP according to a comparative example, different from the example embodiment of the present inventive concept. FIG. 6B illustrates a test region TEG according to at least one example embodiment of the present inventive concepts.

Referring to FIG. 6A, the test region COMP according to a comparative example may include a test pattern TP having a rectangular shape. The AFM may measure a region of a predetermined size thin the test region COMP. Due to a stage error of the AIM, a position of the measurement region may be changed to a first measurement region IR1, a second measurement region IR2, and the like.

When the test region COMP has rectangular metal structures TP, an error in a surface roughness value may increase depending on a measurement region. For example, two intact metal structures TP and two partial metal structures TP may be included in a first measurement region IR1, while four intact metal structures TP may be included in a second measurement region IR2. Even if the metal structures TP have the same step difference, a surface roughness value may vary if areas of the metal structures included in the measurement region are changed. Accordingly, the surface roughness value of the test region COMP according to a comparative example may not accurately reflect a step difference value of the metal structures TP.

Referring to FIG. 6B, a test region TEG according to an example embodiment may include a metal line TL. As described with reference to FIG. 6A, even in the test region TEG, a position of the measurement region may be changed to a first measurement region IR3, a second measurement region IR4, and the like due to a stage error of the AFM.

In the test region TEG, both the first measurement region IR3 and the second measurement region IR4 may span the two metal lines TL. Since the test patterns represented in the first measurement region IR1 and the second measurement region IR2 have the same length in the second direction (Y), an area occupied by the test pattern may be the same in the first measurement region IR1 and the second measurement region IR2, and the surface roughness value may be the same. That is, when the test region TEG includes a line-shaped metal line TL extending in a second direction Y, a stage error in at least the second direction Y will not affect a surface roughness value. Accordingly, the surface roughness value of the test region TEG may more accurately reflect a step difference value of the metal lines TL.

Meanwhile, the size of the test region TEG may be determined based on the size of the measurement region of the AFM and the range of the stage error.

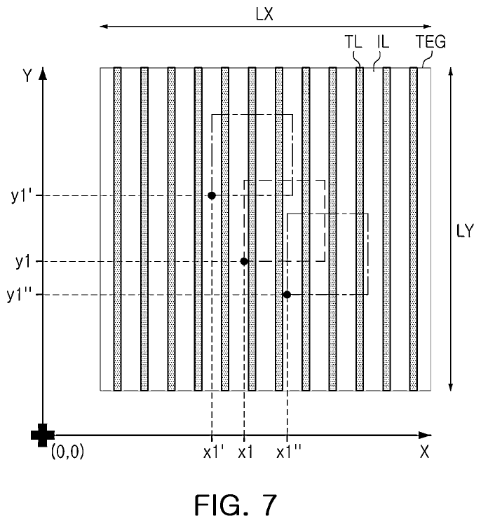

FIG. 7 is a view for illustrating in detail a size of a test region according to at least one example embodiment of the present inventive concepts.

In FIG. 7, a test region TEG including an X-axis and a Y-axis is illustrated on a coordinate system. An AFM may be set to measure a measurement region of a predetermined (or otherwise determined) size from points (x1 and y1) separated by a predetermined distance in X and Y axes from a reference point (0,0) where crosshairs are indicated. The reference point may be any point on the wafer including the test region TEG.

The AFM can have a stage error. For example, when the AFM is set to measure a measurement region of a certain size from the points (x1 and y1) to measure the test region TEG, it may actually measure a measurement region of a certain size from points (x1′ and y1′) or (x1″ and y1″), slightly deviating from the points (x1 and y1).

The size of the test region TEG may be determined so that a measurement region of a certain size from the measurement point does not deviate from the test region TEG even if an actual measurement point deviates from a target point due to a stage error. For example, when an X-axis and Y-axis length of the measurement region is 15 μm and a stage error is ±20 μm, the X-axis length (LX) and the Y-axis length (LY) of the test region TEG may be determined to a value of 55 μm or more based on the length of the measurement region and the range of the stage error.

Meanwhile, the width and the pitch of the metal lines included in the test region TEG may be experimentally determined.

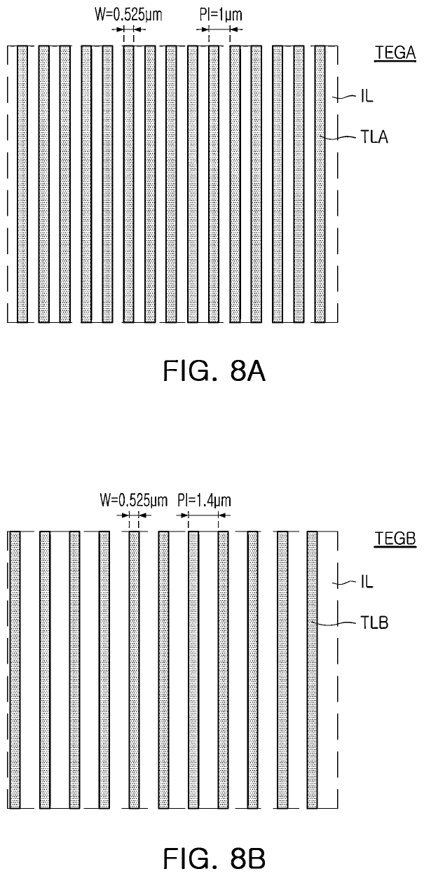

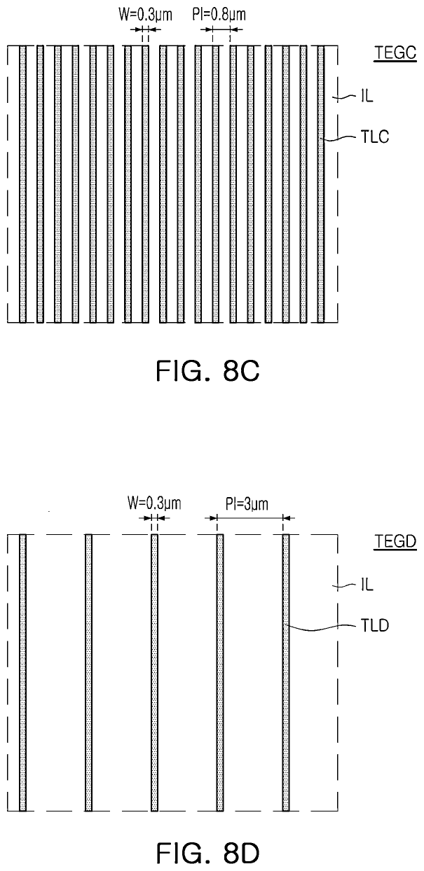

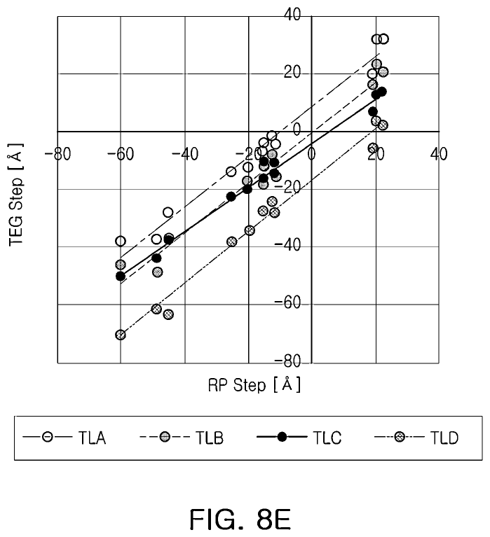

FIGS. 8A to SE are diagrams for illustrating a width and a pitch of a metal line according to some example embodiments of the present inventive concepts.

FIGS. 8A to 8D illustrate test regions TEGA, TEGB, TEGC, and TEGD including, respectively, metal lines TLA, TLB, TLC, and TLD having various line widths W and pitches PI. When the metal lines TL have a line shape having a constant line width W and a pitch PI, a ratio of the line width W and the pitch PI may represent a ratio of the metal lines TL in the test region, that is, pattern density.

In FIGS. 8A to 8D, the line width, pitch, and density of the metal lines TLA may be 0.525 μm, 1 μm, and 52.50%, and the line width, pitch, and density of the metal lines TLB may be 0.525 μm and 1.4. μm, 37.50%, the line width, pitch and density of the metal lines TLC may be 0.3 μm, 0.8 μm, and 37.50%, and the line width, pitch, and density of the metal lines TLD may be 0.3 μm, 3 μm, and 10.00%. That is, the density of the metal lines TLA may be the highest, the density of the metal lines TLB and TLC may be intermediate, and the density of the metal lines TLD may be the lowest.

FIG. 8E is a graph illustrating a correlation between a step difference value of various metal lines TLA, TLB, TLC, and TLD and a step difference value of the bonding pad BP.

Referring to FIG. 8E, a horizontal axis of the graph represents a step difference of the bonding pad BP, and a vertical axis of the graph represents a step difference of the metal lines TL. A correlation between a step difference of various metal lines TLA, TLB, TLC, and TLD and a step difference of the bonding pad BP may be derived by regression analysis. The step difference between the various metal lines TLA, TLB, TLC, and TLD may have a high correlation with the step difference of the bonding pad BP.

According to some example embodiments of the present inventive concepts, when the step difference of the bonding pad BP is included in a target step difference range, a line width W and a pitch PI of the metal lines TL may be selected so that the step difference of the metal lines TL is included in a measurable step difference range.

For example, referring to FIG. 8E, when the step difference of the bonding pad BP is included within a target range of ±10 Å, the step difference of the metal lines TLA, TLB, and TLC may be included within ±20 Å. That is, it may be difficult to monitor whether the step difference of the bonding pad BP is included within a target range by measuring the step differences of the test regions TEGA, TEGB, and TEGC.

On the other hand, when the step difference of the bonding pad BP is included within the target range of ±10 Å, the step difference of the metal lines TLD may be about −20 Å. Monitoring the step difference of the bonding pad BP based on the step difference of the test regions TEM is better than monitoring the step difference of the bonding pad BP based on the step difference of the test regions TEGA, TEGB, and TEGC.

Meanwhile, referring to FIG. 8E, as pattern density decreases, the step difference of the metal lines TLD tends to decrease. Accordingly, when a line width of the metal lines TL is determined to be 0.3 μm, the pitch can be determined to be 3 μm or more so that the density of the metal lines TL is lower than 10.00% of the pattern density of the test region TEGD.

Meanwhile, the line width and the pitch of the metal lines TL are not limited to the examples of FIGS. 8A to 8E, and may vary according to, e.g., the specific method performed during the CMP process.

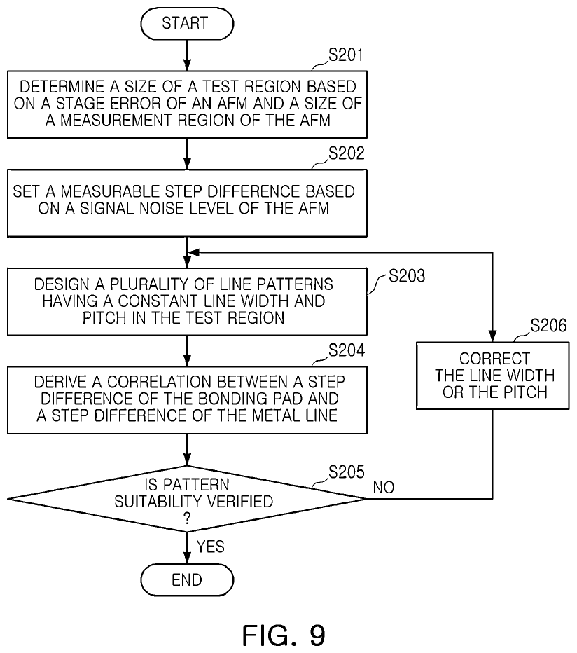

FIG. 9 is a flowchart illustrating a test pattern layout method according to at east one example embodiment of the present inventive concepts.

In operation S201, a size of a test region may be determined based on a stage error of an AFM and a size of a measurement region of the AFM. A specific method of operation S201 has been described in detail with reference to FIG. 7.

In operation S202, a measurable step difference range may be set based on a signal noise level of the AFM. As described above, the AFM may measure a step difference in a range, larger than the signal noise level, and may not detect a step difference, smaller than the signal noise level. Accordingly, the measurable step difference range may be set to a range larger than the signal noise level in a positive direction (and/or a negative direction).

In operation S203, a plurality of line patterns having a constant line width and a constant pitch may be designed to form metal lines in a test region. Meanwhile, a plurality of pad patterns for forming bonding pads may be formed in the semiconductor chip region.

In operation S204, a correlation between a step difference of the bonding pad formed by the pad patterns and a step difference of the metal line formed by the line patterns may be derived. According to at least some embodiments, the operation S204, a step difference value of the bonding pad and a step difference value of the metal line may be manually collected by a designer.

In operation S205, pattern suitability of the metal lines TL may be verified. For example, when the step difference of the bonding pad is included in a target step difference range, it may be verified whether the step difference of the metal lines is included in a measurable step difference range. A specific example of operation S205 has been described in detail with reference to FIG. 8E.

When the verification fails (“No” in operation S205), the line width or the pitch of a plurality of line patterns may be corrected in operation S206. For example, by increasing the pitch of the line patterns, a step difference of the metal lines formed by the line patterns may be adjusted to increase in a negative direction. Then, operations S203 to S205 may be repeated.

When the verification is successful (“Yes” in operation S205), a layout design may be finished, a mask including the line patterns may be manufactured based on the designed layout, and a bonding surface including metal lines may be formed on the wafer with the manufactured mask.

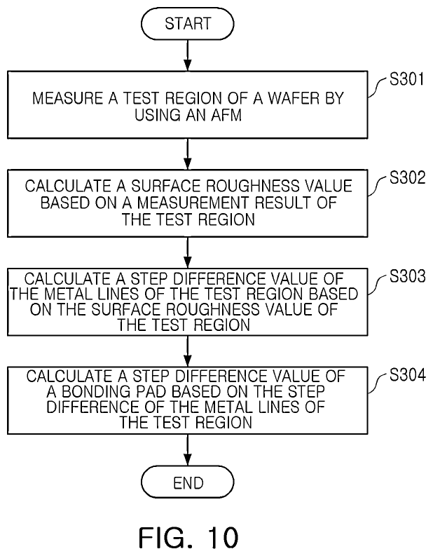

FIG. 10 is a flowchart illustrating an inspection method of a wafer according to at least some example embodiments of the present inventive concepts.

In operation S301, a test region of a wafer may be measured using an AFM. As described with reference to FIG. 7, the AFM may measure a measurement region of a portion of the test regions.

In operation S302, a surface roughness value may be calculated based on a measurement result of the test region. As described above, the surface roughness value may, be determined as a distribution of height values measured over an entire region of the AFM mage (that is, RMS).

In operation S303, a step difference value of the metal lines of the test region may be calculated based on the surface roughness value of the test region. As described above, the surface roughness value of the test region may have a correlation with the step difference value of the metal lines of the test region. The correlation may be experimentally determined in advance using regression analysis, and a step difference value of the line pattern may be calculated using the correlation.

In operation S304, a step difference value of a bonding pad may be calculated or inferred based on the step difference value of the metal line of the test region. As described with reference to FIG. 8E, the step difference value of the metal line of the test region and the step difference value of the bonding pad may have a correlation. According to at least some example embodiments of the present inventive concepts, by measuring a test region including metal lines having a step difference within a measurable range, it may be checked as to whether the step difference of the bonding pad deviating from a measurable step difference range satisfies a target step difference.

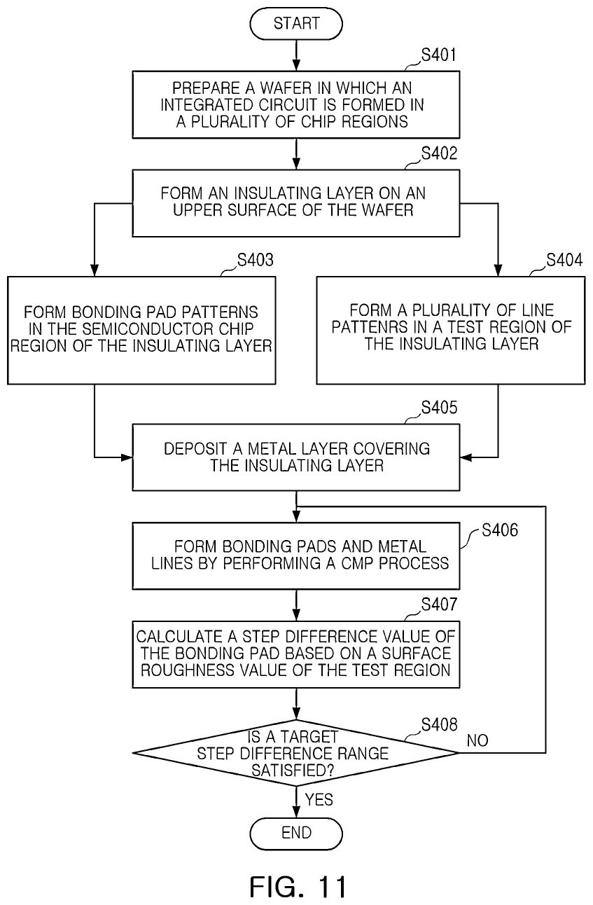

FIG. 11 is a flowchart illustrating a manufacturing method of a wafer according to at least one example embodiments of the present inventive concepts.

In operation S401, a wafer in which an integrated circuit is formed in a plurality of chip regions may be prepared. As described with reference to FIG. 1, logic devices may be formed on a wafer substrate, and an interconnection layer for electrically connecting the logic devices may be formed on an upper surface of the wafer substrate. The logic devices and the interconnection layer may constitute an integrated circuit.

In operation S402, an insulating layer may be formed on an upper surface of the wafer.

In operation S403, bonding pad patterns may be formed in the semiconductor chip region of the insulating layer. In operation S404, a plurality of line patterns having a predetermined (or otherwise determined) line width and a predetermined (or otherwise determined) pitch may be formed in a test region of the insulating layer. As described with reference to FIG. 2, the bonding pad patterns and the line patterns may be formed in a trench shape. Meanwhile, the line patterns may be formed based on a layout designed by the layout method described with reference to FIG. 9.

In operation S405, a metal layer covering the insulating layer, the bonding pad patterns, and the line patterns may be deposited on the insulating layer.

In operation S406, bonding pads and metal lines may be formed by performing a CMP process.

In operation S407, a step difference value of the bonding pad may be calculated based on a surface roughness value of the test region. The method of operation S406 has been described in detail with reference to FIG. 10.

In operation S408, it may be determined whether the step difference of the bonding pad satisfies a target step difference range.

When the target step difference is not satisfied (“No” in operation S408), the step differences of the bonding pads and the metal lines may be adjusted by additionally performing a CMP process in operation S406. Then, operations S407 and S408 may be repeated.

When the target step difference is satisfied (“Yes” in operation S408), wafer manufacturing may be completed and/or may proceed to a subsequent step, such as bonding.

According to at least some example embodiments of the present inventive concepts, it is possible to automatically monitor whether the step difference of the bonding pad satisfies the target step difference and polish the bonding pads so that the step difference of the bonding pad falls within the target step difference range according to the monitoring result. Therefore, mass production of a wafer having a bonding surface can be facilitated.

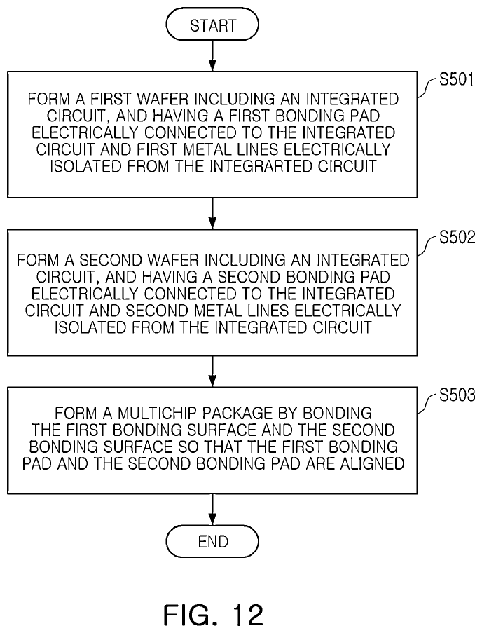

FIG. 12 is a flowchart illustrating a many manufacturing method of a multichip package according to at least some example embodiments of the present inventive concepts.

In operation S501, a first wafer including an integrated circuit, the first wafer having a first bonding pad electrically connected to the integrated circuit and first metal lines electrically isolated from the integrated circuit may be formed on a first bonding surface. For example, the first wafer may include the first semiconductor chip C1 as described with reference to FIG. 1.

According to at least some example embodiments of the present inventive concepts, a step difference value of the first bonding pads may be calculated based on a surface roughness value of a test region including the first metal lines to form a first wafer, and a CMP process may be repeatedly performed until the calculated step difference value falls within a target step difference range.

In operation S502, a second wafer including an integrated circuit, and having a second bonding pad electrically connected to the integrated circuit and second metal lines electrically isolated from the integrated circuit on a second bonding surface may be formed. For example, the second wafer may include the second semiconductor chip C2 as described with reference to FIG. 1.

Similar to forming the first wafer, in order to form the second wafer, a step difference value of the second bonding pads may be calculated based on a surface roughness value of a test region including second metal lines, and a CMP process may be repeatedly performed until the calculated step difference value falls within a target step difference range.

In operation S503, a multichip package in which a first semiconductor chip C1 and a second semiconductor chip C2 are bonded by bonding the first bonding surface and the second bonding surface so that the first bonding pad and the second bonding pad are aligned.

According to at least some example embodiments of the present inventive concepts, the bonding pads of the first semiconductor chip C1 and the second semiconductor chip C2 forming a multichip package may have a step difference within a target step difference range. Accordingly, the bonding quality of the first semiconductor chip C1 and the second semiconductor chip C2 may be improved, and further, a yield of the multichip package may be improved.

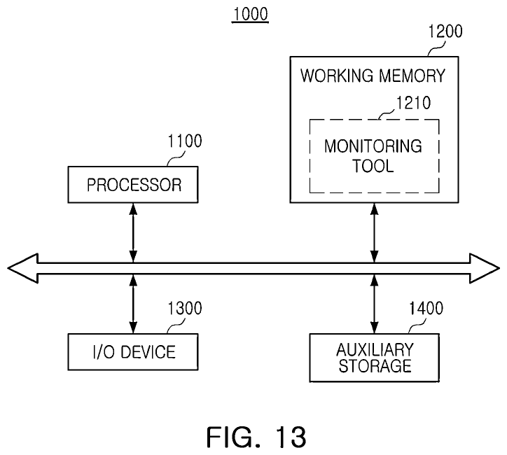

FIG. 13 is a diagram illustrating a monitoring apparatus of a wafer according to at least one example embodiment of the present inventive concepts.

FIG. 13 is a block diagram illustrating a computing system 1000 for performing wafer inspection. Referring to FIG. 13, the computing system 1000 may include at least one processor 1100 connected to the system bus 1001, a working memory 1200, an input/output device 1300, and an auxiliary storage device 1400.

The computing system 1000 may be provided as a dedicated device for wafer inspection. For example, the computing system 1000 may include various design and verification simulation programs. The processor 1100, the working memory 1200, the input/output device 1300, and the auxiliary storage device 1400 may be electrically connected through the system bus 1001 and exchange data with each other. Meanwhile, the configuration of the system bus 1001 is not limited to the above description and may further include mediation means for efficient management.

The processor 1100 may be implemented to execute at least one instruction. For example, the processor 1100 may be implemented to execute software (application programs, operating systems, device drivers) to be executed in the computing system 1000. The processor 1100 may execute an operating system that is loaded into the working memory 1200. The processor 1100 may execute various application programs to be driven based on an operating system. For example, the processor 1100 may be a central processing unit (CPU), a microprocessor, an application processor (AP), a neural processing unit (NPU) and/or any processing device similar thereto.

The working memory 1200 may be implemented to store at least one instruction. For example, the working memory 1200 may be loaded with an operating system or application programs. When the computing system 1000 is booted, an OS image stored in the auxiliary storage device 1400 may be loaded into the working memory 1200 based on a boot sequence. All input/output operations of the computing system 1000 may be supported by the operating system. Similarly, application programs may be loaded into the working memory 1200 to be selected by a user or to provide a basic service. In particular, a monitoring tool 1210 for automatic monitoring of the wafer may be loaded into the working memory 1200.

In addition, the working memory 1200 may be a volatile memory such as dynamic random access memory (DRAM), static random access memory (SRAM), or the like, or a non-volatile memory such as a flash memory, phase change random access memory (PRAM), resistance random access memory (RRAM), nano floating gate memory (NFGM), polymer random access memory (PoRAM), magnetic random access memory (MRAM), ferroelectric random access memory (FRAM), and/or the like.

The input/output device 1300 may control user input and output from user interface devices. For example, the input/output device 1300 may include input means such as a keyboard, a keypad, a mouse, a touch screen, and the like, to receive information from a designer. By using the input/output device 1300, a designer may receive information on a semiconductor region or data paths requiring adjusted operating characteristics. In addition, the input/output device 1300 may include an output means such as a printer, a display, and the like, to display the processing process and result of a design tool 1210 or an OPC tool 1220.

The auxiliary storage device 1400 may be provided as a storage medium of the computing system 1000. The auxiliary storage device 1400 may store application programs, OS images, and various data. The secondary storage device 1400 may be provided in a form of a mass storage device such as a memory card (MMC, eMMC, SD, Micro SD, etc.), a hard disk drive (HDD), a solid state drive (SSD), universal flash storage (UFS), and/or the like. In at least some embodiments, the auxiliary storage device 1400 may include a removable storage medium.

According to at least one example embodiments of the present inventive concepts, the monitoring tool 1210 may acquire an image obtained by measuring a test region of a wafer by AFM from the input/output device 1300. For example, the monitoring tool 1210 may include (or be information ally connected to) an atomic force microscope (AFM). As described above, the test area may include metal lines. The monitoring tool 1210 may calculate a surface roughness value from the image, calculate a step difference value of the metal lines in a test region based on the surface roughness value, and calculate a step difference value of bonding pads included in a semiconductor chip region based on the step difference value of the metal lines.

The monitoring tool 1210 may store the calculated step difference value in the auxiliary storage device 1400 or output the same externally through the input/output device 1300. A CMP equipment may be controlled based on the step difference value output externally, and the bonding pads of the water may be polished to have a target step difference.

As set forth above, according at least some example embodiments of the present inventive concepts, in an inspection method of a wafer using a test pattern having a step difference able to be measured with an atomic force microscope (AFM) on an upper surface of the wafer, even when bonding pads and the insulating layer have minute step differences that are difficult to measure with AFM, a step difference value of the bonding pads and an insulating layer may be monitored.

In a layout design method of a semiconductor according to at least one example embodiment of the present inventive concepts, a test pattern having a step difference measurable by AFM while having a correlation with the step difference of the bonding pads may be designed.

In a manufacturing method of a wafer according to at least one example embodiment of the present inventive concepts, bonding pads and a test pattern are formed on an upper surface of the wafer, and based on a monitoring result using the test pattern, the bonding pads and the insulating layer may have a step difference within a predetermined (or otherwise determined) range.

In a manufacturing method of a multichip package according to at least one example embodiment of the present inventive concepts, adhesion quality between wafers may be improved, and further a yield of the multichip package may be improved.

Herein, a lower side, a lower portion, a lower surface, and the like, are used to refer to a direction toward a mounting surface of the fan-out semiconductor package in relation to cross sections of the drawings, while an upper side, an upper portion, an upper surface, and the like, are used to refer to an opposite direction to the direction. However, these directions are defined for convenience of explanation, and the claims are not particularly limited by the directions defined as described above. For example, if the device in the figures is otherwise oriented (e.g., rotated 90 degrees or at other orientations), the spatially relative descriptors used herein are to be interpreted accordingly.

The meaning of a “connection” of a component to another component in the description includes an indirect connection through an adhesive layer as well as a direct connection between two components. In addition, “electrically connected” conceptually includes a physical connection and a physical disconnection. It can be understood that terms such as “first” and “second”, are used only for a purpose of distinguishing the element from the other elements, and that the element are not otherwise limited thereby. For example, such terms may not limit the sequence or importance of the elements unless otherwise expressly indicated. In some cases, a first element may be referred to as a second element without departing from the scope of the claims set forth herein. Similarly, a second element may also be referred to as a first element without departing from the scope of the claims set forth herein.

The term “example embodiment” used herein does not refer to the same example embodiment, and is provided to emphasize a particular feature or characteristic different from that of another example embodiment. However, example embodiments provided herein are considered to be able to be implemented by being combined in whole or in part one with one another. For example, one element described in a particular example embodiment, even if it is not described in another example embodiment, may be understood as a description related to another example embodiment, unless an opposite or contradictory description is provided therein.

Terms used herein are used only in order to describe an example embodiment rather than limiting the present disclosure. In this case, singular forms include plural forms unless interpreted otherwise in context.

While example embodiments have been shown and described above, it will be apparent to those skilled in the art that modifications and variations could be made without departing from the scope of the present inventive concepts as defined by the appended claims.

1. A method of manufacturing a wafer, the method comprising:
preparing the wafer, including a semiconductor chip region and a test region, such that an integrated circuit is formed in the semiconductor chip region;
forming an insulating layer on an upper surface of the prepared wafer;
forming a bonding pad pattern in the semiconductor chip region of the insulating layer;
forming a line pattern having a constant line width and a constant pitch in the test region of the insulating layer;
depositing a metal layer on the insulating layer;
polishing the metal layer using a chemical mechanical polishing (CMP) process such that bonding pads and metal lines are formed based on the bonding pad pattern and the line pattern, respectively;
determining a surface roughness value of the test region by measuring the test region in which the metal lines are formed using an atomic force microscope (AFM);
determining a step difference value of the bonding pads of the semiconductor chip region with respect to the insulating layer, based on the surface roughness value of the test region; and
selectively performing the CMP process when the step difference value of the bonding pads is not within a target step difference tolerance range.

2. The manufacturing method of the wafer of claim 1, wherein the integrated circuit comprises logic circuits included in a substrate of the wafer, interconnections connecting the logic circuits, and vias vertically connecting the interconnections,
the bonding pads contact the vias, and
the metal lines are horizontally separated from the vias.

3. The manufacturing method of the wafer of claim 1, wherein the insulating layer is formed of silicon carbon nitride (SiCN), and
at least one of the bonding pads and the metal lines are formed of copper (Cu).

4. The manufacturing method of the wafer of claim 1, wherein the surface roughness value of the test region is determined based on a dispersion of a height value in an overall region of an image measured by the AFM.

5. The manufacturing method of the wafer of claim 1, wherein the wafer comprises main chip regions and a scribe lane partitioning the main chip regions,
wherein the test region is included in at least one of a portion of the main chip regions or in the scribe lane.

6. The manufacturing method of the wafer of claim 1, wherein determining the step difference value of the bonding pads comprises
determining a step difference value of the metal lines based on the surface roughness value of the test region; and
determining the step difference value of the bonding pads based on the determined step difference value of the metal lines.

7. The manufacturing method of the wafer of claim 1, wherein the target step difference tolerance range of the bonding pads is less than a measurable step difference range of the AFM, and
a step difference range of the metal lines is within the measurable step difference range of the AFM.

8. The manufacturing method of the wafer of claim 7, wherein the metal lines are recessed with respect to an insulating layer.

9. An inspection method of a wafer including a semiconductor chip region and a test region, the method comprising:
measuring a measurement region included in the test region with an atomic force microscope (AFM), the measurement region including a plurality of metal lines having a constant line width and a constant pitch;
determining a surface roughness value of the test region based on a result of the measuring of the measurement region;
determining a step difference value of the metal lines of the test region based on the surface roughness value; and
determining a step difference value of bonding pads in the semiconductor chip region based on the step difference value of the metal lines.

10. The inspection method of the wafer of claim 9, wherein
the determining the step difference value of the metal lines is based on a correlation between the surface roughness value determined in advance by regression analysis.

11. The inspection method of the wafer of claim 9, wherein
the determining the step difference value of the bonding pads is based on a correlation between the step difference value of the metal lines determined in advance by regression analysis.

12. The inspection method of the wafer of claim 9, wherein, the step difference value of the bonding pads is smaller than a signal noise level of the AFM and the step difference value of the line patterns is larger than the signal noise level of the AFM.

13. A layout method for a semiconductor wafer, the layout method comprising:
determining a size of a test region based on a stage error of an atomic force microscope (AFM) and a size of a measurement region of the AFM;
setting a measurable step difference range based on a signal noise level of the AFM;
designing a bonding pad pattern in a semiconductor chip region of the semiconductor wafer,
designing a line pattern having a constant line width and a constant pitch in the test region of the semiconductor wafer;
deriving a correlation between a step difference of bonding pads and a step difference of metal lines, the bonding pads and the metal lines generated based on the bonding pad pattern and the line pattern, respectively;
verifying, based on the correlation, whether the step difference of the metal lines is included in the measurable step difference range when the step difference of the bonding pads is included in a target step difference range; and
selectively adjusting at least one of the line width or the pitch of the line pattern based on a result of the verifying whether the step difference of the metal lines is included in the measurable step difference range.

14. The layout method of the semiconductor wafer of claim 13, wherein the measurable step difference range is set to a larger range in at least one of a positive or negative direction than the signal noise level of the AFM.

15. The layout method of the semiconductor wafer of claim 13, wherein the measurable step difference range is ±20 Å or more.

16. The layout method of the semiconductor wafer of claim 13, wherein the target step difference range deviates from the measurable step difference range.

17. The layout method of the semiconductor wafer of claim 13, wherein the target step difference range is ±10 Å or less.

18. The layout method of the semiconductor wafer of claim 13, wherein the selectively adjusting at least one of the line width or the pitch of the metal lines comprises adjusting the pitch of a plurality of line patterns upwardly in order to adjust the step difference of the metal lines upwardly in a negative direction.

19. The layout method of the semiconductor wafer of claim 13, wherein horizontal and vertical lengths of the test region are each 55 μm or more.

20. The layout method of the semiconductor wafer of claim 13, wherein the bonding pad patterns have a rectangular shape.

21. (canceled)

22. (canceled)
